(19) United States
(12) Patent Application Publication
(10) Pub. No.: US 2025/0201664 A1
(43) Pub. Date: Jun. 19, 2025

(54) LIQUID METAL ENCAPSULATION DEVICE

(71) Applicant: DONGGUAN ZIITEK ELECTRONICAL MATERIAL AND TECHNOLOGY LTD., Dongguan (CN)

(72) Inventors: Chih-Sheng Liao, Dongguan (CN); Dongyang Jiang, Dongguan (CN); Yongliang Huang, Dongguan (CN)

(21) Appl. No.: 19/068,011

(22) Filed: Mar. 3, 2025

(30) Foreign Application Priority Data
Jan. 13, 2025 (CN) 202520086362.0

(51) Int. Cl. H01L 23/433

(52) U.S. Cl. CPC H01L 23/4334

(57) ABSTRACT

A liquid metal encapsulation device includes a sealing frame and a heat dissipation member. The sealing frame includes a frame body, a first elastic sealing ring, and a second elastic sealing ring. A chip is disposed on the frame body, an annular groove is formed between the chip and the frame body, the first elastic sealing ring is embedded at a bottom of the annular groove, and the second elastic sealing ring is arranged around an outer periphery of the frame body. The heat dissipation member is mounted on an end face of the frame body and together with the chip, the first elastic sealing ring, and the frame body forms a sealed space for filling liquid metal, and the frame body has multiple holes and is compressible. The device can achieve efficient heat conduction and reliably seal the liquid metal under pressure.

### CROSS REFERENCE TO RELATED APPLICATIONS

The present application claims the benefit of Chinese Patent Application No. 202520086362.0 filed on Jan. 13, 2025, the contents of which are incorporated herein by reference in their entirety.

### FIELD OF THE APPLICATION

The present application relates to the field of chip heat dissipation, and particularly to a liquid metal encapsulation device.

### BACKGROUND OF THE APPLICATION

In electronic devices, the heat dissipation of chips is of paramount importance. With the advancement of semiconductor technology, the integration density and power density of chips have been continuously increasing, leading to a significant rise in heat generation. Therefore, efficient thermal management solutions are becoming increasingly critical to ensure the performance and reliability of devices. Thermal conductive materials, as key components connecting heat-generating elements (such as chips) with heat dissipation members (such as copper or aluminum heat sinks, thermal conductive copper tubes, etc.), play an indispensable role in this process. Traditional thermal conductive materials are typically composed of metal oxides mixed with inorganic powders, which offer good insulation properties to prevent short-circuit risks. However, their thermal conductivity is limited by the inherent characteristics of the materials, resulting in insufficient performance in efficient heat dissipation. On the other hand, liquid metals, with their high thermal conductivity, are ideal thermal conductive media. Nevertheless, their application is greatly restricted due to the potential short-circuit risks caused by their electrical conductivity.

To address the short-circuit issues potentially caused by liquid metals, various solutions have been proposed in the industry. For example, Chinese Patent CN216749870U discloses a liquid metal encapsulation device that uses compressible organic polymer materials (such as silicone or rubber) to restrict the flow of liquid metal. However, in practical applications, this configuration is prone to trapping air when pressure is applied to the upper and lower ends of the encapsulation device, forming a large air cavity. Since air is a poor conductor of heat, this significantly increases the overall thermal resistance, thereby greatly reducing the heat conduction efficiency. Additionally, Taiwan Patent TWM651021 proposes using a metal frame as an enclosure. Although this method takes advantage of the strength and stability of metal, the rigidity of metal materials, lack of elasticity, and compressibility lead to poor sealing performance, which increase the risk of enclosure failure. Therefore, these existing methods face many limitations in practical applications, including but not limited to low thermal conduction efficiency and unstable sealing performance, failing to fully meet the requirements for efficient heat dissipation and reliable sealing.

Therefore, there is an urgent need for a liquid metal encapsulation device to address the above deficiencies.

### SUMMARY OF THE APPLICATION

In view of the aforementioned issues, the purpose of the present application is to provide a liquid metal encapsulation device that can achieve efficient heat conduction and reliably seal the liquid metal under pressure.

In order to achieve the purpose mentioned above, the present application provides a liquid metal encapsulation device for heat dissipation of a chip, including a sealing frame and a heat dissipation member. The sealing frame includes a frame body, a first elastic sealing ring, and a second elastic sealing ring, a middle area of the frame body is provided with an accommodation area, in which a chip is placed. An annular groove is formed between the chip and the frame body, the first elastic sealing ring is embedded at a bottom of the annular groove, and the second elastic sealing ring is arranged around an outer periphery of the frame body. The heat dissipation member is mounted on an end face of the frame body and together with the chip, the first elastic sealing ring, and the frame body forms a sealed space for filling liquid metal, and the frame body includes multiple holes and is compressible.

Compared with the prior art, on one hand, the frame body of the liquid metal encapsulation device of the present application has multiple holes, which provide a pathway for air discharging during pressurization and additional space to accommodate excess liquid metal to prevent overflow. On the other hand, the frame body has certain compressibility, which can deform slightly when pressure is applied, helping to completely expel internal air and ensuring the uniform distribution of the liquid metal, thereby reducing the risk of large voids forming and achieving efficient heat conduction.

However, the inventors of the present application found in practical testing that, although the holes in the frame body are helpful for absorbing and storing the liquid metal, under pressurized conditions, the liquid metal may still seep through the tiny gaps between the chip and the frame body due to factors such as uneven interfaces. Based on this, the first elastic sealing ring of the present application is disposed at the bottom of the annular groove between the chip and the frame body, which can closely adhere to the bottom of the annular groove under pressurized conditions, thereby effectively preventing the liquid metal from seeping through the gaps between the chip and the frame body. Meanwhile, the second elastic sealing ring is arranged around the outer periphery of the frame body, and the external edge of the frame body is completely sealed, thereby further preventing the liquid metal from leaking from the external edge of the frame body. Therefore, the combined use of the first and second elastic sealing rings ensures that the liquid metal encapsulation device can effectively seal the liquid metal even under pressure. In summary, the liquid metal encapsulation device of the present application achieves efficient heat conduction and reliable sealing of the liquid metal under pressure.

Further, the first elastic sealing ring and the second elastic sealing ring are independently made of silicone, epoxy resin, polyurethane, rubber, or polyester resin.

Further, the frame body is made of porous silicone, aerogel, polyurethane foam material, or glass fiber material.

Further, a height of the first elastic sealing ring is lower than that of the chip.

Further, the height of the first elastic sealing ring is ¼ to ¾ of that of the frame body.

Further, a height of the second elastic sealing ring is not less than that of the frame body.

Further, an open porosity of the frame body ranges from 10% to 80%.

Further, the open porosity of the frame body ranges from 40% to 60%.

Further, a cross-sectional shape of the holes in the frame body is at least one of circular, elliptical, triangular, and polygonal.

Further, a height of the frame body ranges from 0.5 mm to 5.0 mm.

### BRIEF DESCRIPTION OF THE DRAWINGS

FIG. 1 is a sectional view of the liquid metal encapsulation device of the present application.

FIG. 2 is a top view of the liquid metal encapsulation device of the present application with the heat dissipation member removed.

### DETAILED DESCRIPTION OF ILLUSTRATED EMBODIMENTS

To provide a detailed explanation of the technical content, and structural features of the present application, the following is further explained in conjunction with the implementation method and the accompanying drawings.

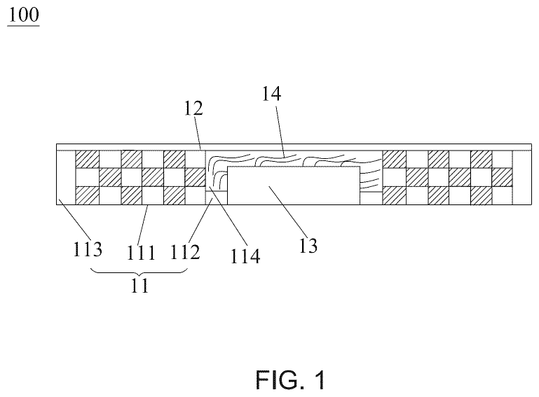

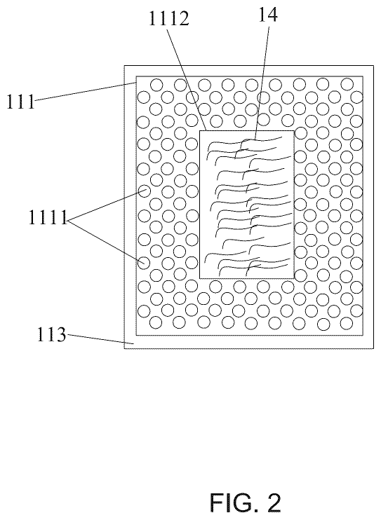

Referring to FIGS. 1 and 2, the present application provides a liquid metal encapsulation device 100, which not only achieves efficient heat conduction but also reliably seals liquid metal under pressure. Therefore, the liquid metal encapsulation device 100 of the present application is particularly suitable for the heat dissipation of chips such as CPUs and GPUs that require efficient heat management, which can significantly improve heat dissipation efficiency and prevent potential short-circuit risks. Specifically, the liquid metal encapsulation device 100 of the present application includes a sealing frame 11 and a heat dissipation member 12. The sealing frame 11 includes a frame body 111, a first elastic sealing ring 112 and a second elastic sealing ring 113. The middle area of the frame body 111 has an accommodation area 1112, in which a chip 13 is placed. An annular groove 114 is formed between the chip 13 and the frame body 111. The first elastic sealing ring 112 is embedded at the bottom of the annular groove 114, and the second elastic sealing ring 113 is arranged around the outer periphery of the frame body 111. The heat dissipation member 12 is mounted on the end face of the frame body 111 and, together with the chip 13, the first elastic sealing ring 112, and the frame body 111, forms a sealed space for filling liquid metal 14.

The frame body 111 includes multiple holes 1111, which provide a pathway for air discharging during pressurization and also create additional space to accommodate the excess liquid metal 14, thereby preventing it from overflowing. The frame body 111 also has certain compressibility, allowing it to deform slightly when pressure is applied. This configuration helps to completely expel the internal air and ensures the uniform distribution of the liquid metal 14, thereby reducing the risk of large voids forming and achieving efficient heat conduction.

Despite the fact that the holes 1111 in the frame body 111 are helpful for absorbing and storing the liquid metal 14, due to factors such as uneven interfaces, the liquid metal 14 may still seep out through the tiny gaps between the chip 13 and the frame body 111 under pressurized conditions. To address this issue, the first elastic sealing ring 112 of the present application is placed at the bottom of the annular groove 114 between the chip 13 and the frame body 111. Under pressure, the first elastic sealing ring 112 is closely adhered to the bottom of the annular groove 114, effectively preventing the liquid metal 14 from seeping through the gaps between the chip 13 and the frame body 111. Meanwhile, the second elastic sealing ring 113 is arranged around the outer periphery of the frame body 111 to ensure that the external edge of the frame body 111 is completely sealed, preventing the liquid metal 14 from leaking from the external edge of the frame body 111. Therefore, the combined use of the first the clastic sealing ring 112 and the second elastic sealing ring 113 ensures that the liquid metal 14 can be reliably sealed even under pressure. As a result, the liquid metal encapsulation device 100 of the present application achieves efficient heat conduction and reliable sealing of the liquid metal 14.

Specifically, the heat dissipation member 12 can be made of copper or aluminum heat dissipation fins. The heat dissipation member 12 covers the end face of the frame body 111 and, together with the chip 13, the first elastic sealing ring 112, and the frame body 111, forms a sealed space for filling liquid metal 14. The liquid metal 14 may be, but is not limited to, Sn/In/Ga-based alloys or Sn/In/Bi-based alloys. The melting point of Sn/In/Ga-based alloys is below room temperature, while that of Sn/In/Bi-based alloys is around 50° C. to 60° C. The alloy type can be selected according to the operating environment of the electronic device. When the electronic device generates heat above the melting point of the liquid metal 14 during operation, the liquid metal 14 in the sealed space transitions from solid to liquid. This transition is accompanied by an increase in the volume of liquid metal 14. As the volume of liquid metal 14 increases, the excess liquid metal 14 enters the frame body 111. Through the capillary phenomenon caused by the multiple holes 1111 in the frame body 111, the excess liquid metal 14 is absorbed into the holes 1111 and solidified. Therefore, the frame body 111 can prevent the liquid metal 14 from overflowing onto other electrical contact points, thereby preventing potential short-circuit problems.

Specifically, the frame body 111 can be made of porous organic materials, such as porous silicone, aerogel, polyurethane foam materials, or glass fiber materials (e.g., fiberglass cloth or fiberglass cotton). The height of the frame body 111 can be 0.5 mm to 5.0 mm. These materials are electrical insulators, so there is no risk of short circuit even if they are used in large quantities. In addition, these materials have abundant porous and certain compressibility, which allows the liquid metal encapsulation device 100 to deform under the assembly pressure to reduce thickness and allow internal air to be smoothly expelled through the holes 1111, thereby effectively reducing the thermal resistance. Therefore, the frame body 111 can effectively absorb a certain amount of the liquid metal 14 through the capillary phenomenon, thereby improving heat conduction efficiency while preventing the excessive liquid metal 14 from overflowing and avoiding the risk of short circuit in electronic devices.

It is worth noting that the porosity of the frame body 111 has a direct impact on its ability to absorb the liquid metal 14 and expel air. If the porosity is too high, the capillary action cannot be effectively formed, thereby weakening the ability to absorb the liquid metal 14. Conversely, if the porosity is too low, it will limit the storage space for the liquid metal 14 and may hinder air discharging, thereby increasing the thermal resistance. Therefore, to ensure the optimal performance, the porosity of the frame body 111 is set between 10% and 80%, with a preferred range of 40% to 60%. In addition, the cross-sectional shape of the holes 1111 may be circular as shown in FIG. 2, or elliptical, triangular, polygonal, or a combination of these shapes. In such a way, it not only provides a pathway for air discharging during the pressurization but also accommodates the excess liquid metal 14 to prevent the overflow.

Specifically, both the first elastic sealing ring 112 and the second elastic sealing ring 113 are made of elastic materials. The first clastic scaling ring 112 is made of materials such as silicone, epoxy resin, polyurethane, rubber, or polyester resin. The height of the first elastic sealing ring 112 is lower than that of the chip 13 and is set to be between 1/4 and 3/4 of the height of the frame body 111. Under pressurized conditions, the first elastic sealing ring 112 can be closely adhered to the bottom of the annular groove 114, thereby effectively preventing the liquid metal 14 from leaking through the tiny gaps between the chip 13 and the frame body 111. The second elastic sealing ring 113 is arranged around the outer periphery of the frame body 111 and is also made of materials such as silicone, epoxy resin, polyurethane, rubber, or polyester resin. The height of the second elastic sealing ring 113 is not less than that of the frame body 111, so as to ensure that the external edge of the frame body 111 is completely sealed, thereby further preventing the liquid metal 14 from leaking from the external edge of the frame body 111.

In summary, the liquid metal encapsulation device 100 of the present application includes the sealing frame 11 and the heat dissipation member 12. The sealing frame 11 includes a frame body 111, a first elastic sealing ring 112 and a second elastic sealing ring 113. The middle area of the frame body 111 has an accommodation area 1112, in which a chip 13 is placed. An annular groove 114 is formed between the chip 13 and the frame body 111. The first elastic sealing ring 112 is embedded at the bottom of the annular groove 114, and the second elastic sealing ring 113 is arranged around the outer periphery of the frame body 111. The heat dissipation member 12 is mounted on the end face of the frame body 111 and, together with the chip 13, the first elastic sealing ring 112, and the frame body 111, forms a sealed space for filling liquid metal 14. On one hand, the frame body 111 has multiple holes 1111, which provide a pathway for air discharging during pressurization and additional space to accommodate excess liquid metal 14 to prevent overflow. On the other hand, the frame body 111 has certain compressibility, which can deform slightly when pressure is applied, helping to completely expel internal air and ensuring the uniform distribution of the liquid metal 14, thereby reducing the risk of large voids forming and achieving efficient heat conduction. Further, the first elastic sealing ring 112 is disposed at the bottom of the annular groove 114 between the chip 13 and the frame body 111, it can closely adhere to the bottom of the annular groove 114 under pressurized conditions, thereby effectively preventing the liquid metal 14 from seeping through the gaps between the chip 13 and the frame body 111. Meanwhile, the second elastic sealing ring 113 is arranged around the outer periphery of the frame body 111, and the external edge of the frame body 111 is completely sealed, preventing the liquid metal 14 from leaking from the external edge of the frame body 111. Therefore, the liquid metal 14 encapsulation device 100 of the present application achieves efficient heat conduction and reliable sealing of liquid metal 14.

The above disclosure is only preferred embodiments of the present application and cannot be used to limit the scope of rights of the present application. Therefore, any equivalent changes made in accordance with the claims of the present application are within the scope of the present application.

What is claimed is:

1. A liquid metal encapsulation device for heat dissipation of a chip, comprising a sealing frame and a heat dissipation member, wherein the sealing frame comprises a frame body, a first elastic sealing ring, and a second elastic sealing ring, a middle area of the frame body is provided with an accommodation area, in which a chip is placed, an annular groove is formed between the chip and the frame body, the first elastic sealing ring is embedded at a bottom of the annular groove, and the second elastic sealing ring is arranged around an outer periphery of the frame body, the heat dissipation member is mounted on an end face of the frame body and together with the chip, the first elastic sealing ring, and the frame body forms a sealed space for filling liquid metal, and the frame body comprises multiple holes and is compressible.

2. The liquid metal encapsulation device according to claim 1, wherein the first elastic sealing ring and the second elastic sealing ring are independently made of silicone, epoxy resin, polyurethane, rubber, or polyester resin.

3. The liquid metal encapsulation device according to claim 1, wherein the frame body is made of porous silicone, aerogel, polyurethane foam material, or glass fiber material.

4. The liquid metal encapsulation device according to claim 1, wherein a height of the first elastic sealing ring is lower than that of the chip.

5. The liquid metal encapsulation device according to claim 4, wherein the height of the first elastic sealing ring is ¼ to ¾ of that of the frame body.

6. The liquid metal encapsulation device according to claim 1, wherein a height of the second elastic sealing ring is not less than that of the frame body.

7. The liquid metal encapsulation device according to claim 1, wherein an open porosity of the frame body ranges from 10% to 80%.

8. The liquid metal encapsulation device according to claim 7, wherein the open porosity of the frame body ranges from 40% to 60%.

9. The liquid metal encapsulation device according to claim 1, wherein a cross-sectional shape of the holes in the frame body is at least one of circular, elliptical, triangular, and polygonal.

10. The liquid metal encapsulation device according to claim 1. wherein a height of the frame body ranges from 0.5 mm to 5.0 mm.
